(19) United States
(12) Patent Application Publication
(10) Pub. No.: US 2026/0190411 A1
(43) Pub. Date: Jul. 2, 2026

(54) SEMICONDUCTOR STRUCTURE AND MANUFACTURING METHOD THEREOF

(71) Applicant: Enkris Semiconductor, Inc., Suzhou (CN)

(72) Inventors: Jiaqi HE, Suzhou (CN); Kai CHENG, Suzhou (CN)

(21) Appl. No.: 19/243,367

(22) Filed: Jun. 19, 2025

(30) Foreign Application Priority Data
Jan. 2, 2025 (CN) 202510020507.1

(51) Int. Cl. H10D 62/60; H10D 30/01; H10D 30/47

(52) U.S. Cl. CPC H10D 62/60; H10D 30/015; H10D 30/481

(57) ABSTRACT

A semiconductor structure includes a substrate, a channel layer, a source N-type doped layer, a drain N-type doped layer, a barrier layer, a source metal layer, a first P-type semiconductor layer, a gate metal layer, a second P-type semiconductor layer, and a drain metal layer. The channel layer is disposed above the substrate. The side of the channel layer facing away from the substrate includes a source region, a drain region, and an intermediate region between the source region and the drain region. The side of the barrier layer facing away from the substrate includes a gate region. The source metal layer is disposed on the side of the source N-type doped layer facing away from the substrate. The first P-type semiconductor layer and the gate metal layer are stacked in sequence in the gate region.

### CROSS-REFERENCE TO RELATED APPLICATION(S)

This application claims priority to Chinese Patent Application No. 202510020507.1 filed Jan. 2, 2025, the disclosure of which is incorporated herein by reference in its entirety.

### TECHNICAL FIELD

Embodiments of this disclosure relate to the field of semiconductor technologies, for example, a semiconductor structure and a manufacturing method thereof.

### BACKGROUND

A high-electron-mobility transistor (HEMT) is a field-effect transistor that utilizes a heterojunction formed by two materials with different bandgaps and provides a channel for carrier transport. HEMTs operate at high frequencies. The drain region of an HEMT is required to withstand a high electric field but cannot effectively block electron transition, resulting in a degradation of the dynamic performance of the HEMT under a high voltage.

### SUMMARY

Embodiments of this disclosure provide a semiconductor structure and a manufacturing method thereof to improve the dynamic performance of the semiconductor structure under a high voltage.

According to a first aspect, an embodiment of this disclosure provides a semiconductor structure. The semiconductor structure includes a substrate, a channel layer, a source N-type doped layer, a drain N-type doped layer, a barrier layer, a source metal layer, a first P-type semiconductor layer, a gate metal layer, a second P-type semiconductor layer, and a drain metal layer. The channel layer is disposed above the substrate. The side of the channel layer facing away from the substrate includes a source region, a drain region, and an intermediate region between the source region and the drain region. The source N-type doped layer is disposed in the source region. The drain N-type doped layer is disposed in the drain region. The barrier layer is disposed in the intermediate region. The side of the barrier layer facing away from the substrate includes a gate region. The source metal layer is disposed on the side of the source N-type doped layer facing away from the substrate. The first P-type semiconductor layer and the gate metal layer are stacked in sequence in the gate region. The second P-type semiconductor layer is located on the side of the drain N-type doped layer close to the gate region and in contact with the drain N-type doped layer. The drain metal layer is disposed on the side of the second P-type semiconductor layer facing away from the substrate and the side of the drain N-type doped layer facing away from the substrate.

According to a second aspect, an embodiment of this disclosure provides a manufacturing method of a semiconductor structure. The manufacturing method of the semiconductor structure includes sequentially epitaxially forming a channel layer, a barrier layer, and a P-type semiconductor layer on a substrate; forming a source N-type doped layer in a source region of the channel layer and forming a drain N-type doped layer in a drain region of the channel layer; forming a gate metal layer, a source metal layer, and a drain metal layer on the side of the barrier layer facing away from the substrate, where the gate metal layer is located in the gate region, the source metal layer is located on the side of the source N-type doped layer facing away from the substrate, the drain metal layer is located on the side of the drain N-type doped layer facing away from the substrate, and the orthographically projected area of the drain metal layer on the substrate is greater than the orthographically projected area of the drain N-type doped layer on the substrate; and with the gate metal layer, the source metal layer, and the drain metal layer as masks, etching the P-type semiconductor layer to form a first P-type semiconductor layer between the gate metal layer and the barrier layer and form a second P-type semiconductor layer between the drain metal layer and the barrier layer.

### BRIEF DESCRIPTION OF DRAWINGS

FIG. 1 is a section view of a semiconductor structure according to an embodiment of this disclosure.

FIG. 2 is a perspective view of the semiconductor structure of FIG. 1 according to an embodiment of this disclosure.

FIG. 3 is a top view of a semiconductor structure without source metal layer, drain metal layer, and gate metal layer according to an embodiment of this disclosure.

FIG. 4 is a top view of a semiconductor structure without source metal layer, drain metal layer, and gate metal layer according to an embodiment of this disclosure.

FIG. 5 is a top view of a semiconductor structure without source metal layer, drain metal layer, and gate metal layer according to an embodiment of this disclosure.

FIG. 6 is a section view of a semiconductor structure according to an embodiment of this disclosure.

FIG. 7 is a section view of a semiconductor structure according to an embodiment of this disclosure.

FIG. 8 is a section view of a semiconductor structure according to an embodiment of this disclosure.

FIG. 9 is a section view of a semiconductor structure according to an embodiment of this disclosure.

FIG. 10 is a section view of a semiconductor structure according to an embodiment of this disclosure.

FIG. 11 is a section view of a semiconductor structure according to an embodiment of this disclosure.

FIG. 12 is a section view of a semiconductor structure according to an embodiment of this disclosure.

FIG. 13 is a section view of a semiconductor structure according to an embodiment of this disclosure.

FIG. 14 to FIG. 18 illustrate an intermediate structure of a semiconductor structure according to an embodiment of this disclosure.

FIG. 19 illustrates an intermediate structure of a semiconductor structure according to an embodiment of this disclosure.

FIG. 20 to FIG. 22 illustrate an intermediate structure of a semiconductor structure according to an embodiment of this disclosure.

FIG. 23 to FIG. 26 illustrate an intermediate structure of a semiconductor structure according to an embodiment of this disclosure.

FIG. 27 illustrates an intermediate structure of a semiconductor structure according to an embodiment of this disclosure.

FIG. 28 illustrates an intermediate structure of a semiconductor structure according to an embodiment of this disclosure.

FIG. 29 is a perspective view of a semiconductor structure according to an embodiment of this disclosure.

FIG. 30 is a perspective view of a semiconductor structure according to an embodiment of this disclosure.

### DETAILED DESCRIPTION

For a better understanding of solutions of this disclosure by those skilled in the art, solutions in embodiments of this disclosure are described clearly and completely hereinafter in conjunction with the drawings in embodiments of this disclosure. Apparently, the embodiments described hereinafter are part, not all, of embodiments of this disclosure. Based on embodiments of this disclosure, all other embodiments obtained by those of ordinary skill in the art on the premise that no creative work is done are within the scope of this disclosure.

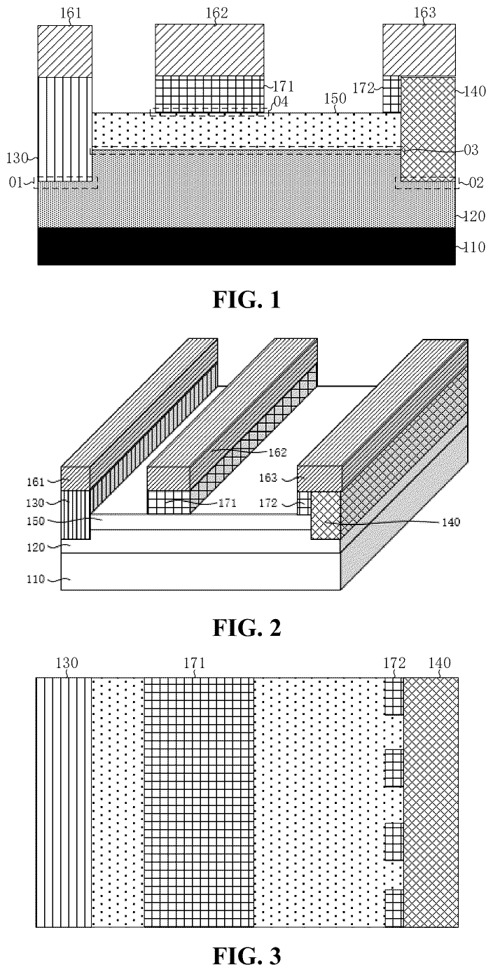

FIG. 1 is a section view of a semiconductor structure according to an embodiment of this disclosure. FIG. 2 is a perspective view of the semiconductor structure of FIG. 1 according to an embodiment of this disclosure. As shown in FIG. 1 and FIG. 2, the semiconductor structure includes a substrate 110, a channel layer 120, a source N-type doped layer 130, a drain N-type doped layer 140, a barrier layer 150, a source metal layer 161, a first P-type semiconductor layer 171, a gate metal layer 162, a second P-type semiconductor layer 172, and a drain metal layer 163. The channel layer 120 is disposed above the substrate 110. The side of the channel layer 120 facing away from the substrate 110 includes a source region 01, a drain region 02, and an intermediate region 03 between the source region 01 and the drain region 02. The source N-type doped layer 130 is disposed in the source region 01. The drain N-type doped layer 140 is disposed in the drain region 02. The barrier layer 150 is disposed in the intermediate region 03. The side of the barrier layer 150 facing away from the substrate 110 includes a gate region 04. The source metal layer 161 is disposed on the side of the source N-type doped layer 130 facing away from the substrate 110. The first P-type semiconductor layer 171 and the gate metal layer 162 are stacked in sequence in the gate region 04. The second P-type semiconductor layer 172 is located on the side of the drain N-type doped layer 140 close to the gate region 04 and in contact with the drain N-type doped layer 140. The drain metal layer 163 is disposed on the side of the second P-type semiconductor layer 172 facing away from the substrate 110 and the side of the drain N-type doped layer 140 facing away from the substrate 110.

The channel layer 120 and the barrier layer 150 form a heterojunction. A two-dimensional electron gas (2DEG) channel is formed on the surface of the channel layer 120 close to the barrier layer 150. When no voltage is applied to the semiconductor device, the first P-type semiconductor layer 171 can deplete the 2DEG at the channel so that an enhanced device is formed. The source N-type doped layer 130 is located between the source metal layer 161 and the channel layer 120. The source N-type doped layer 130 is in ohmic contact with the source metal layer 161, reducing the ohmic contact resistance between the source metal layer 161 and the channel layer 120. Similarly, the drain N-type doped layer 140 is in ohmic contact with the drain metal layer 163, reducing the ohmic contact resistance between the drain metal layer 163 and the channel layer 120. This reduces the overall resistance of the semiconductor structure and thus improves the electrical performance of the semiconductor structure.

In addition, the second P-type semiconductor layer 172 and the drain N-type doped layer 140 form a PN junction, reducing the high electric field withstood by the drain of the semiconductor device under a high voltage, effectively blocking electrons from being trapped by an interface trap between the gate and the drain, and thus improving the dynamic performance of the semiconductor device under a high voltage.

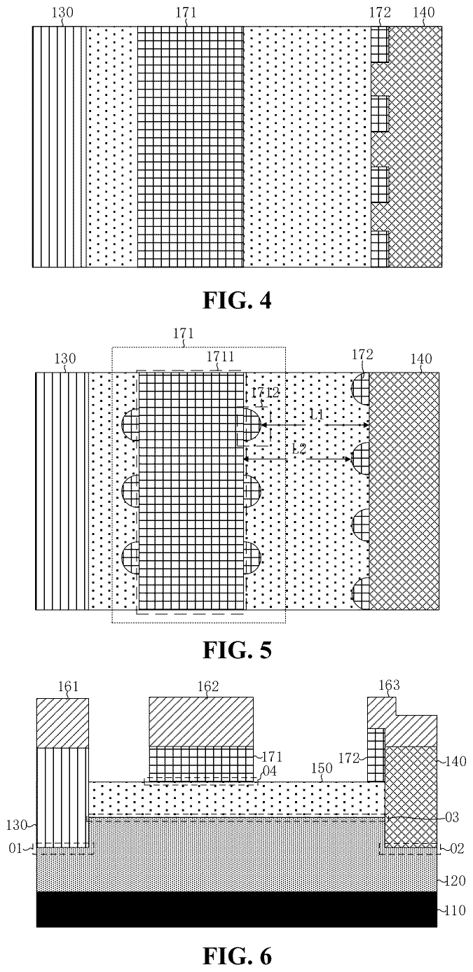

Based on the previous embodiments, optionally, FIG. 3 is a top view of a semiconductor structure without source metal layer, drain metal layer, and gate metal layer according to an embodiment of this disclosure, and FIG. 4 is a top view of a semiconductor structure without source metal layer, drain metal layer, and gate metal layer according to an embodiment of this disclosure. As shown in FIG. 3 and FIG. 4, multiple second P-type semiconductor layers 172 are spaced apart in the extension direction of the drain N-type doped layer 140.

Each second P-type semiconductor layer 172 is located on the side of the drain N-type doped layer 140 close to the gate region 04 and is in contact with the drain N-type doped layer 140, or each second P-type semiconductor layer 172 is embedded in the drain N-type doped layer 140. Thus, for each second P-type semiconductor layer 172, the second P-type semiconductor layer 172 and the drain N-type doped layer 140 in contact with the second P-type semiconductor layer 172 can form a PN junction, reducing the high electric field withstood by the drain of the semiconductor device under a high voltage, effectively blocking electrons from being trapped by the interface trap between the gate and the drain, and thus improving the dynamic performance of the semiconductor device under a high voltage. Compared with the structure shown in FIG. 3, in the structure shown in FIG. 4, the contact area between the second P-type semiconductor layer 172 and the drain N-type doped layer 140 is larger, and the PN junction region is larger, better blocking electrons from being trapped by the interface trap between the gate and the drain and improving the dynamic performance of the device.

Based on the previous embodiments, optionally, FIG. 5 is a top view of a semiconductor structure without source metal layer, drain metal layer, and gate metal layer according to an embodiment of this disclosure. The first P-type semiconductor layer 171 includes a P-type body portion 1711 and multiple P-type protruding portions 1712 spaced apart. The P-type protruding portions 1712 are located on the side of the P-type body portion 1711 close to the drain N-type doped layer 140. The P-type protruding portions 1712 and the second P-type semiconductor layers 172 are staggered in the extension direction of the gate metal layer, improving the current uniformity of the device and avoiding local overheating caused by current blockage.

Based on the previous embodiments, optionally, with continued reference to FIG. 5, the minimum distance L1 from each P-type protruding portion 1712 to the drain N-type doped layer 140 is equal to the minimum distance L2 from the P-type body portion 1711 to each second P-type semiconductor layer 172. Specifically, L1 is equal to L2, that is, the distance from the integral structure formed by the drain N-type doped layer 140 and each second P-type semiconductor layer 172 to the first P-type semiconductor layer 171 is substantially consistent, improving the current uniformity of the device and avoiding local overheating caused by current blockage. Optionally, the contour of the side of the first P-type semiconductor layer 171 facing the drain N-type doped layer 140 is complementary to the contour of the side of the integral structure formed by the drain N-type doped layer 140 and each second P-type semiconductor layer 172 facing the first P-type semiconductor layer 171, better improving the current uniformity of the device.

Based on the previous embodiments, this disclosure provides multiple arrangements of the drain N-type doped layer and each second P-type semiconductor layer 172. The following describes several arrangements of the drain N-type doped layer and each second P-type semiconductor layer 172 by way of example.

Optionally, FIG. 6 is a section view of a semiconductor structure according to an embodiment of this disclosure. As shown in FIG. 6, the distance from the surface of the drain N-type doped layer 140 facing away from the substrate 110 to the substrate 110 is less than the distance from the surface of the second P-type semiconductor layer 172 facing away from the substrate 110 to the substrate 110, and the height of the second P-type semiconductor layer is larger, providing a smoother electric field distribution for a side of the gate close to the drain and reducing current collapse.

Optionally, with continued reference to FIG. 1, the surface of the drain N-type doped layer 140 facing away from the substrate 110 is flush with the surface of the second P-type semiconductor layer 172 facing away from the substrate 110.

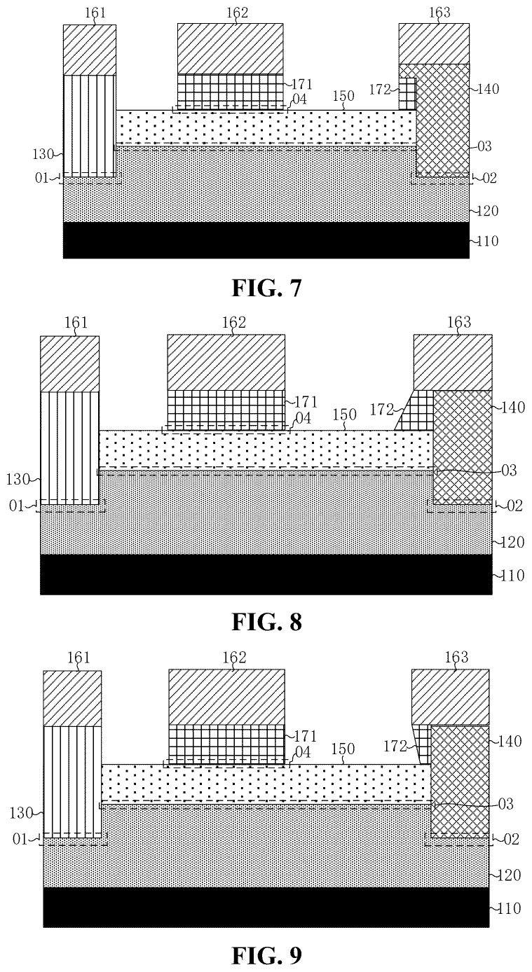

Optionally, FIG. 7 is a section view of a semiconductor structure according to an embodiment of this disclosure. As shown in FIG. 7, the distance from the surface of the drain N-type doped layer 140 facing away from the substrate 110 to the substrate 110 is greater than the distance from the surface of the second P-type semiconductor layer 172 facing away from the substrate 110 to the substrate 110, the drain N-type doped layer 140 covers multiple surfaces of the second P-type semiconductor layer 172, and the contact area between the second P-type semiconductor layer 172 and the drain N-type doped layer 140 is larger, increasing the PN junction region, better blocking electrons from being trapped by the interface trap between the gate and the drain, and improving the dynamic performance of the device.

Based on the previous embodiments, this disclosure provides multiple arrangements of the sidewall of the second P-type semiconductor layer. The following describes several arrangements of the sidewall of the second P-type semiconductor layer by way of example.

Optionally, as shown in FIG. 1, the sidewall of the second P-type semiconductor layer 172 is perpendicular to the plane where the substrate 110 is located. Optionally, the sidewall of the drain metal layer 163 close to the gate metal layer 162 is flush with the sidewall of the second P-type semiconductor layer 172 facing away from the drain N-type doped layer 140. Specifically, the second P-type semiconductor layer 172 with a vertical sidewall is formed by etching with the drain metal layer 163 as a mask. The metal self-alignment process can reduce the steps in one etching, simplify the manufacturing process of the semiconductor device, and improve the manufacturing efficiency of the semiconductor device.

Optionally, FIG. 8 is a section view of a semiconductor structure according to an embodiment of this disclosure, and FIG. 9 is a section view of a semiconductor structure according to an embodiment of this disclosure. As shown in FIG. 8 and FIG. 9, the angle between the sidewall of the second P-type semiconductor layer 172 and the plane where the substrate 110 is located is an acute angle. Specifically, a slope is formed on the side of the second P-type semiconductor layer 172 close to the gate metal layer 162, providing a smooth electric field distribution for a side of the gate close to the drain and reducing current collapse.

Optionally, as shown in FIG. 1, the first P-type semiconductor layer 171 and the second P-type semiconductor layer 172 are both located on the side of the barrier layer 150 facing away from the substrate 110. Moreover, in the direction perpendicular to the plane where the substrate 110 is located, the thickness of the first P-type semiconductor layer 171 is equal to the thickness of the second P-type semiconductor layer 172.

Specifically, the first P-type semiconductor layer 171 and the second P-type semiconductor layer 172 are formed simultaneously in the epitaxial process, involving a simple process.

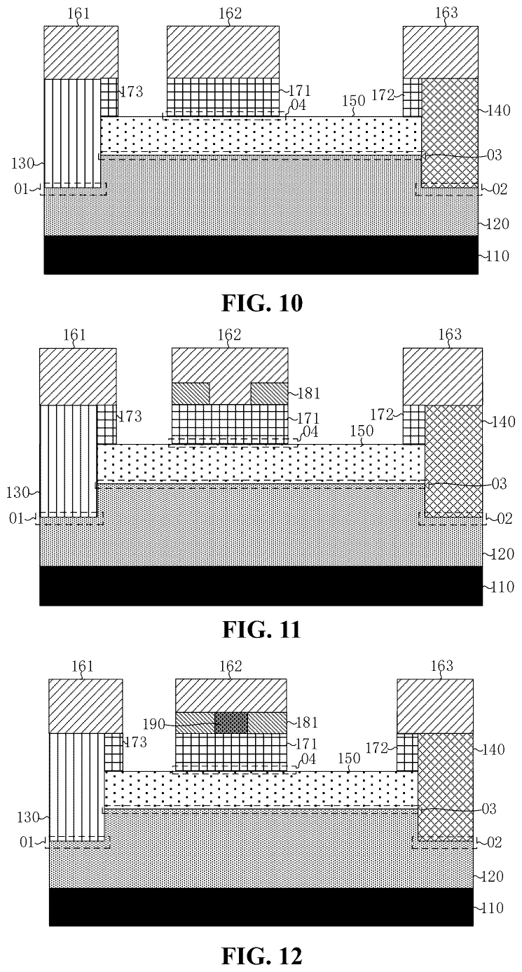

Optionally, FIG. 10 is a section view of a semiconductor structure according to an embodiment of this disclosure. As shown in FIG. 10, the semiconductor structure also includes a third P-type semiconductor layer 173. The third P-type semiconductor layer 173 is located on the side of the source N-type doped layer 130 close to the gate region 04 and is in contact with the source N-type doped layer 130. The source metal layer 161 is disposed on the side of the third P-type semiconductor layer 173 facing away from the substrate 110 and the side of the source N-type doped layer 130 facing away from the substrate 110.

The third P-type semiconductor layer 173 is in contact with the source N-type doped layer 130 to form a PN junction, alleviating uneven electric field distribution when the side of the gate of the semiconductor device facing the source is in the on state, increasing the gate breakdown voltage.

Optionally, as shown in FIG. 10, the first P-type semiconductor layer 171, the second P-type semiconductor layer 172, and the third P-type semiconductor layer 173 are all located on the side of the barrier layer 150 facing away from the substrate 110. Moreover, in the direction perpendicular to the plane where the substrate 110 is located, the thickness of the first P-type semiconductor layer 171, the thickness of the second P-type semiconductor layer 172, and the thickness of the third P-type semiconductor layer 173 are equal.

Optionally, with continued reference to FIG. 10, the sidewall of the source metal layer 161 close to the gate metal layer 162 is flush with the sidewall of the third P-type semiconductor layer 173 facing away from the source N-type doped layer 130. This can be implemented by a metal self-alignment process of the source metal layer 161, simplifying the manufacturing process of the semiconductor device and improving the manufacturing efficiency of the semiconductor device.

Optionally, with continued reference to FIG. 1 and FIG. 10, the sidewall of the gate metal layer 162 is flush with the sidewall of the first P-type semiconductor layer 171. This can be implemented by a metal self-alignment process of the gate metal layer 162, simplifying the manufacturing process of the semiconductor device and improving the manufacturing efficiency of the semiconductor device. Specifically, with the source metal layer 161, the gate metal layer 162, and the drain metal layer 163 as hard masks, the P-type semiconductor layer is etched to form the first P-type semiconductor layer 171, the second P-type semiconductor layer 172, and the third P-type semiconductor layer 173.

Optionally, FIG. 11 is a section view of a semiconductor structure according to an embodiment of this disclosure. As shown in FIG. 11, the semiconductor structure also includes a first blocking layer 181. The first blocking layer 181 is disposed between the gate metal layer 162 and the first P-type semiconductor layer 171. The first blocking layer 181 includes an opening structure. The gate metal layer 162 is electrically connected to the first P-type semiconductor layer 171 through the opening structure.

The first blocking layer 181 is provided with the opening structure. Part of the gate metal layer 162 is disposed in the opening of the opening structure. The contact between the gate metal layer 162 and the first P-type semiconductor layer 171 is achieved through the opening of the opening structure, enabling the electrical connection between the gate metal layer 162 and the first P-type semiconductor layer 171. In this case, the gate metal layer 162 is a T-shaped gate structure. When the size of the gate metal layer is reduced to below 0.5 μm, the T-shaped gate can improve the small signal characteristic of the device, such as the cut-off frequency and the maximum oscillation frequency, facilitating the application of the GaN device in the radio frequency field.

Optionally, the P-type impurity concentration in part of the first P-type semiconductor layer 171 covered by the first blocking layer 181 is equal to or lower than the P-type impurity concentration in part of the first P-type semiconductor layer 171 exposed by the opening structure.

Specifically, the P-type impurities are activated before the first blocking layer is formed so that the P-type impurities in the first P-type semiconductor layer 171 are approximately equal. Alternatively, the P-type impurities are activated after the opening structure in the first blocking layer 181 is formed so that the P-type impurity concentration in part of the first P-type semiconductor layer 171 covered by the first blocking layer 181 is lower than the P-type impurity concentration in part of the first P-type semiconductor layer 171 exposed by the opening structure. In this case, the P-type impurity concentration at the sidewall of the first P-type semiconductor layer 171 is lower, reducing the gate leakage. Alternatively, after the sidewall of the gate metal layer 162 is aligned with the sidewall of the first P-type semiconductor layer 171 in the metal self-alignment process, the side surface of the first P-type semiconductor layer 171 is exposed. During annealing activation, the exposed side surface forms an H ion escape channel to activate the first P-type semiconductor layer 171.

Specifically, the material of the first blocking layer 181 includes any one of in-situ SiN, ex-situ SiN, in-situ AlN, ex-situ AlN, aluminum oxide, or SiO₂.

Since in-situ SiN, ex-situ SiN, in-situ AlN, ex-situ AlN, aluminum oxide, and SiO₂ are all insulating materials, the first blocking layer 181 composed of any one of these materials is required to be provided with an opening structure so that the gate metal layer 162 is electrically connected to the first P-type semiconductor layer 171 through the opening structure. It is to be noted that in-situ refers to manufacturing in the same manufacturing reaction chamber, involving a simple process and avoiding impurities introduced due to replacement of the chamber.

Optionally, FIG. 12 is a section view of a semiconductor structure according to an embodiment of this disclosure. As shown in FIG. 12, the semiconductor structure also includes an aluminum-containing film layer 190. The aluminum-containing film layer 190 is located in the opening structure. The gate metal layer 162 is electrically connected to the first P-type semiconductor layer 171 through the aluminum-containing film layer 190 in the opening structure.

The band gap of the aluminum-containing film layer 190 in the opening structure is greater than the band gap of the first P-type semiconductor layer 171, increasing the Schottky barrier height between the gate metal layer 162 and the first P-type semiconductor layer 171 and increasing the breakdown voltage.

Optionally, in the direction parallel to the plane where the substrate 110 is located, the widths of the first blocking layers 181 located on the two sides of the opening structure are equal. Alternatively, the width of the first blocking layer 181 located on the side of the opening structure close to the drain metal layer 163 is greater than the width of the first blocking layer 181 located on the side of the opening structure close to the source metal layer 161.

Optionally, the material of the aluminum-containing film layer 190 includes at least one of AlN, AlON, or Al₂O₃. Illustratively, if the aluminum-containing film layer 190 is a two-layer structure, the material of the aluminum-containing film layer 190 may include AlN and AlON; AlON and Al₂O₃; or AlN and Al₂O₃. Illustratively, if the aluminum-containing film layer 190 is a three-layer structure, the material of the aluminum-containing film layer 190 may include AlN, AlON, and Al2O3 that are stacked. The oxygen composition in the aluminum-containing film layer 190 gradually increases in the direction away from the substrate 110. Illustratively, when the aluminum-containing film layer 190 is a gradient structure, the oxygen composition in the aluminum-containing film layer 190 gradually increases in the direction away from the substrate 110, improving the anti-penetration capability of the gate region and improving the reliability of the device. Moreover, the compactness of the aluminum-containing film layer 190 can reduce the electron scattering on the surface of the first P-type semiconductor layer 171 and reduce the gate leakage current.

It is to be noted that when the material of the aluminum-containing film layer 190 is AlN and the material of the first blocking layer 181 is in-situ AlN or ex-situ AlN, it may be considered that the upper surface of the first P-type semiconductor layer 171 is entirely covered by the AlN material. The aluminum-containing film layer 190 and the first blocking layer 181 are made of the same material, simplifying the manufacturing process.

Optionally, in the direction perpendicular to the plane where the substrate 110 is located, the thickness of the aluminum-containing film layer 190 is less than or equal to the thickness of the first blocking layer 181, reducing the influence on the rectification characteristic of the gate Schottky junction. When the thickness of the aluminum-containing film layer 190 is less than the thickness of the first blocking layer 181, the gate metal layer 162 is still a T-shaped gate structure. The T-shaped gate can improve the small signal characteristic of the device, such as the cut-off frequency and the maximum oscillation frequency, facilitating the application of the GaN device in the radio frequency field.

Optionally, the semiconductor structure also includes a GaN layer. The GaN layer is filled in the opening structure. The gate metal layer is electrically connected to the first P-type semiconductor layer through the GaN layer in the opening structure. Referring to FIG. 12, the position of the GaN layer is the same as the position of the aluminum-containing film layer 190. Optionally, the material of the GaN layer is either N-type doped GaN or unintentionally doped GaN. The GaN layer and the underlying first P-type semiconductor layer 171 form a PN junction, reducing the surface potential and better reducing the leakage current. Alternatively, the material of the GaN layer is P-type doped GaN. The P-type doping concentration of the GaN layer is low, about 1E16/cm³-1E17/cm³. The P-type doping concentration of the first P-type semiconductor layer 171 is greater than or equal to 1E18/cm³. The GaN layer and the underlying first P-type semiconductor layer 171 form a homo-junction with a carrier concentration difference, reducing the surface potential and better reducing the leakage.

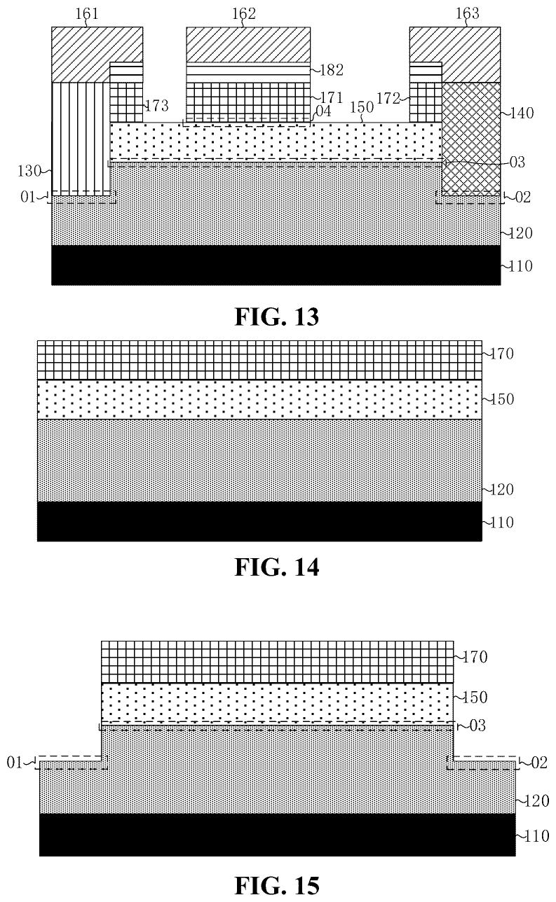

Optionally, FIG. 13 is a section view of a semiconductor structure according to an embodiment of this disclosure. As shown in FIG. 13, the semiconductor structure also includes a second blocking layer 182. The second blocking layer 182 is disposed between the first P-type semiconductor layer 171 and the gate metal layer 162. The material of the second blocking layer 182 includes TiN. The second blocking layer 182 and the p-type gate form a Schottky junction. This front-gate process structure can avoid damage to the surface of the first p-type semiconductor layer 171 caused by subsequent process steps. Specifically, the p-type gate is an integral structure formed by the first P-type semiconductor layer 171 and the gate metal layer 162.

In addition, as shown in FIG. 13, the second blocking layer 182 is also disposed between the second P-type semiconductor layer 172 and the drain metal layer 163 to prevent the surface of the second P-type semiconductor layer 172 from being damaged in the subsequent manufacturing process.

As shown in FIG. 13, the second blocking layer 182 is also disposed between the third P-type semiconductor layer 173 and the source metal layer 161 to prevent the surface of the third P-type semiconductor layer 173 from being damaged in the subsequent manufacturing process.

An embodiment of this disclosure provides a manufacturing method of a semiconductor structure. FIG. 14 to FIG. 19 illustrate an intermediate structure of a semiconductor structure according to an embodiment of this disclosure. The manufacturing method of the semiconductor structure includes the following steps:

In S110, as shown in FIG. 14, a channel layer 120, a barrier layer 150, and a P-type semiconductor layer 170 are sequentially epitaxially formed above a substrate 110.

The material of the substrate 110 includes sapphire, Si, SiC, diamond, or GaN. The substrate 110 is the base of the semiconductor structure that can provide a support function. The channel layer 120 and the barrier layer 150 may be made of a GaN-based semiconductor material. For example, the material of the channel layer 120 is GaN, and the material of the barrier layer 150 is AlGaN. The channel layer 120 and the barrier layer 150 form a heterojunction. A 2DEG channel is formed on the surface of the channel layer 120 close to the barrier layer 150. The channel layer 120 and the barrier layer 150 may be manufactured by atomic layer deposition, or chemical vapor deposition, or molecular beam epitaxial growth, or plasma enhanced chemical vapor deposition, or low pressure chemical evaporation deposition, or physical vapor deposition, or metal organic source molecular beam epitaxy, or metal organic compound chemical vapor deposition, or a combination thereof. The material of the P-type semiconductor layer 170 is a P-type GaN-based material. Optionally, the material of the P-type semiconductor layer 170 is P-type GaN.

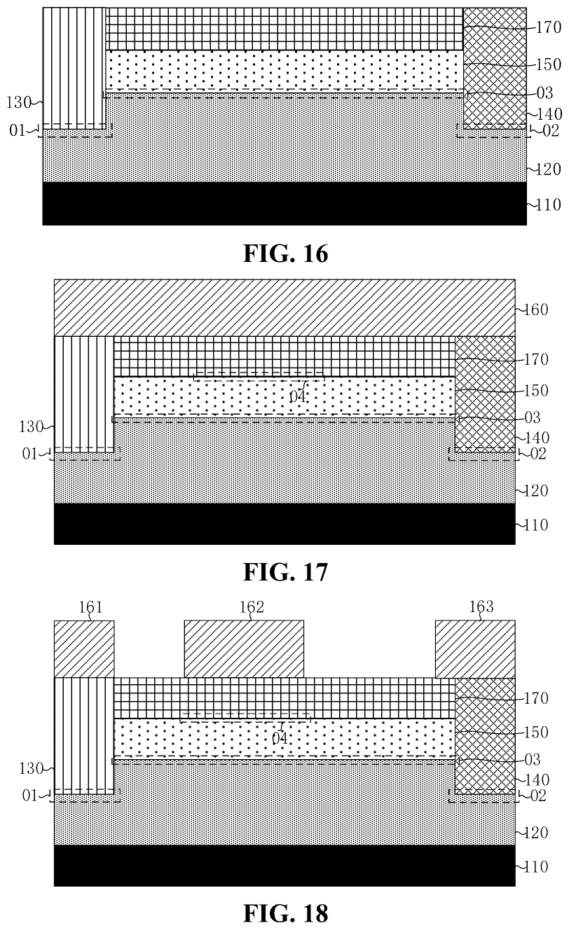

In S120, as shown in FIG. 16, a source N-type doped layer 130 is formed in a source region 01 of the channel layer 120, and a drain N-type doped layer is formed in a drain region 02 of the channel layer 120.

In an embodiment, as shown in FIG. 15, a recess in the source region 01 and a recess in the drain region 02 are formed by etching through the P-type semiconductor layer 170, the barrier layer 150, and part of the channel layer 120.

As shown in FIG. 16, a source N-type doped layer 130 is secondarily epitaxially formed in the recess in the source region 01, and a drain N-type doped layer 140 is secondarily epitaxially formed in the recess in the drain region 02. It is to be noted that the source N-type doped layer 130 and the drain N-type doped layer 140 are made of the same material, such as N-type GaN, and are simultaneously epitaxially formed. It is to be noted that an SiO₂ isolation layer is formed on the upper surface of the P-type semiconductor layer 170, and then only the N-type doped layer is selectively epitaxially grown in the recess.

In another embodiment, as shown in FIG. 16, N-type ions are implanted into the P-type semiconductor layer 170, the barrier layer 150, and part of the channel layer 120 disposed in the source region 01 and the drain region 02 of the channel layer 120 to form the source N-type doped layer 130 and the drain N-type doped layer 140.

In S130, as shown in FIG. 17 and FIG. 18, a gate metal layer 162, a source metal layer 161, and a drain metal layer 163 are formed on the side of the barrier layer 150 facing away from the substrate 110. The gate metal layer 162 is located in the gate region 04. The source metal layer 161 is located on the side of the source N-type doped layer 130 facing away from the substrate 110. The drain metal layer 163 is located on the side of the drain N-type doped layer 140 facing away from the substrate 110. The orthographically projected area of the drain metal layer 163 on the substrate 110 is greater than the orthographically projected area of the drain N-type doped layer 140 on the substrate 110.

The metal material layer 160 is deposited on the entire surface and patterned to form the gate metal layer 162 located in the gate region 04, the source metal layer 161 located on the source N-type doped layer 130, and the drain metal layer 163 located on the drain N-type doped layer 140. For example, a patterned photoresist is formed on the metal material layer 160. With the photoresist as a mask, part of the metal material layer 160 is removed by etching. It is to be noted that in FIG. 18, part of the metal material layer 160 between the gate region 04 and the drain N-type doped layer 140 and part of the metal material layer 160 between the gate region 04 and the source N-type doped layer 130 are removed by etching.

In S140, as shown in FIG. 1, with the gate metal layer 162, the source metal layer 161, and the drain metal layer 163 as masks, the P-type semiconductor layer 170 is etched to form a first P-type semiconductor layer 171 between the gate metal layer 162 and the barrier layer 150 and form a second P-type semiconductor layer 172 between the drain metal layer 163 and the barrier layer 150.

When no voltage is applied to the semiconductor device, the first P-type semiconductor layer 171 can deplete the 2DEG at the channel, enabling an enhanced device; and the second P-type semiconductor layer 172 is in contact with the drain N-type doped layer 140 to form a PN junction, reducing the high electric field withstood by the drain of the semiconductor device under a high voltage, effectively blocking electrons from being trapped by the interface trap between the gate and the drain, and improving the dynamic performance of the semiconductor device under a high voltage.

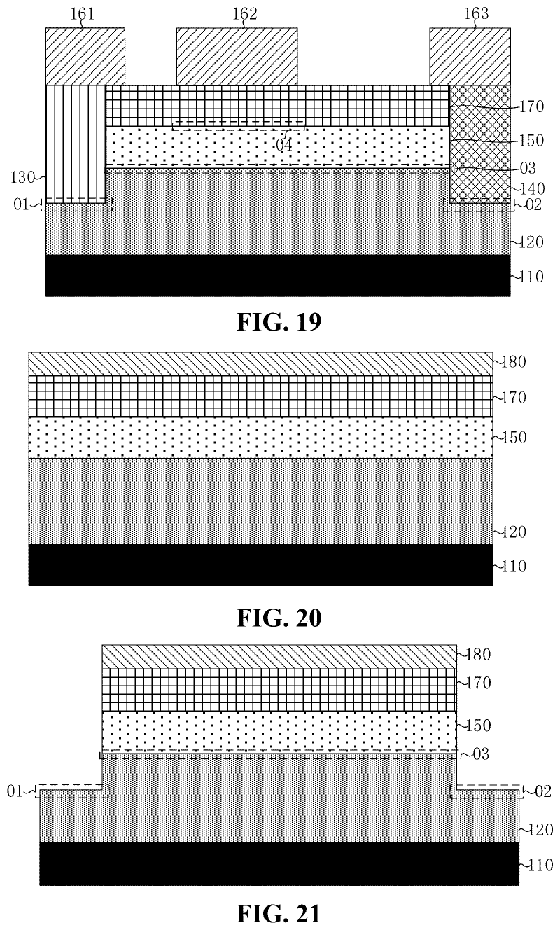

In addition, with the gate metal layer 162, the source metal layer 161, and the drain metal layer 163 as masks, the P-type semiconductor layer 170 is etched to easily form the second P-type semiconductor layer 172 through the metal self-alignment process. Moreover, the sidewall of the drain metal layer 163 close to the gate metal layer 162 is flush with the sidewall of the second P-type semiconductor layer 172 facing away from the drain N-type doped layer 140, and the sidewall of the gate metal layer 162 is flush with the sidewall of the first P-type semiconductor layer 171. Further, the sidewall of the gate metal layer 162 is flush with the sidewall of the first P-type semiconductor layer 171. This can improve the ability of the P-type gate to control the underlying channel. Optionally, FIG. 19 illustrates an intermediate structure of a semiconductor structure according to an embodiment of this disclosure. With reference to FIG. 19 and FIG. 10, with the gate metal layer 162, the source metal layer 161, and the drain metal layer 163 as masks, etching the P-type semiconductor layer 170 also includes the following: the orthographically projected area of the source metal layer 161 on the substrate 110 is greater than the orthographically projected area of the source N-type doped layer 130 on the substrate 110 so that a third P-type semiconductor layer 173 is formed between the source metal layer 161 and the barrier layer 150.

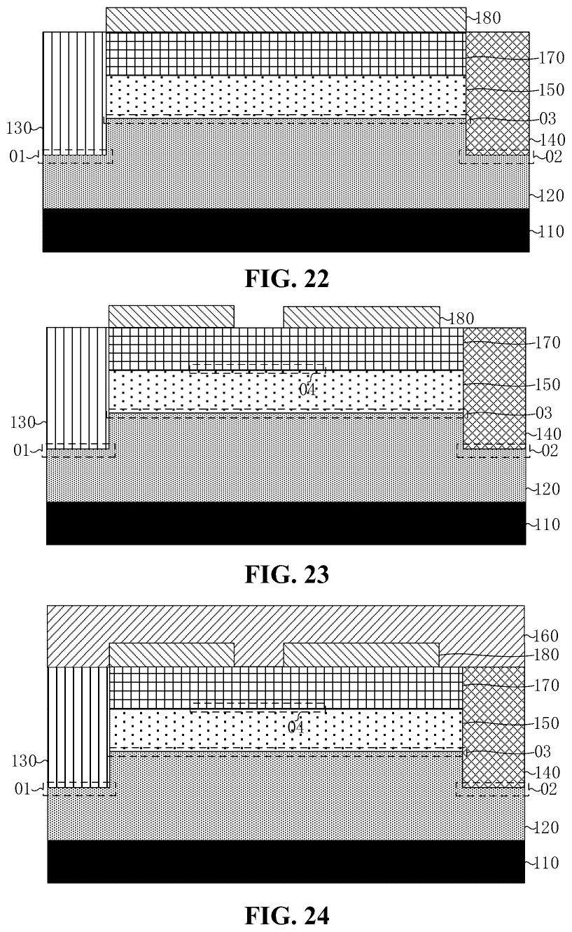

Based on the previous embodiments, optionally, FIG. 20 to FIG. 22 illustrate an intermediate structure of a semiconductor structure according to an embodiment of this disclosure. After the channel layer 120, the barrier layer 150, and the P-type semiconductor layer 170 are sequentially epitaxially formed above the substrate 110, the manufacturing method also includes S210. In S210, as shown in FIG. 20, a passivation layer 180 is epitaxially formed on the side of the P-type semiconductor layer 170 facing away from the substrate 110. The manufacturing method also includes S220. In S220, as shown in FIG. 21, a recess in the source region 01 and a recess in the drain region 02 are formed by etching through the passivation layer 180, the P-type semiconductor layer 170, the barrier layer 150, and part of the channel layer 120. The manufacturing method also includes S230. In S230, as shown in FIG. 22, with the passivation layer 180 as a mask, a source N-type doped layer 130 is secondarily epitaxially formed in the recess in the source region 01, and a drain N-type doped layer 140 is secondarily epitaxially formed in the recess in the drain region 02.

FIG. 23 to FIG. 26 illustrate an intermediate structure of a semiconductor structure according to an embodiment of this disclosure. If the material of the passivation layer 180 includes any one of in-situ SiN, ex-situ SiN, in-situ AlN, ex-situ AlN, aluminum oxide, or SiO₂, after the source N-type doped layer 130 and the drain N-type doped layer 140 are secondarily epitaxially formed, the manufacturing method also includes S310. In S310, as shown in FIG. 23, part of the passivation layer 180 corresponding to the gate region 04 and part of the passivation layer 180 adjacent to the drain N-type doped layer 140 are etched to form an opening structure exposing part of the P-type semiconductor layer 170.

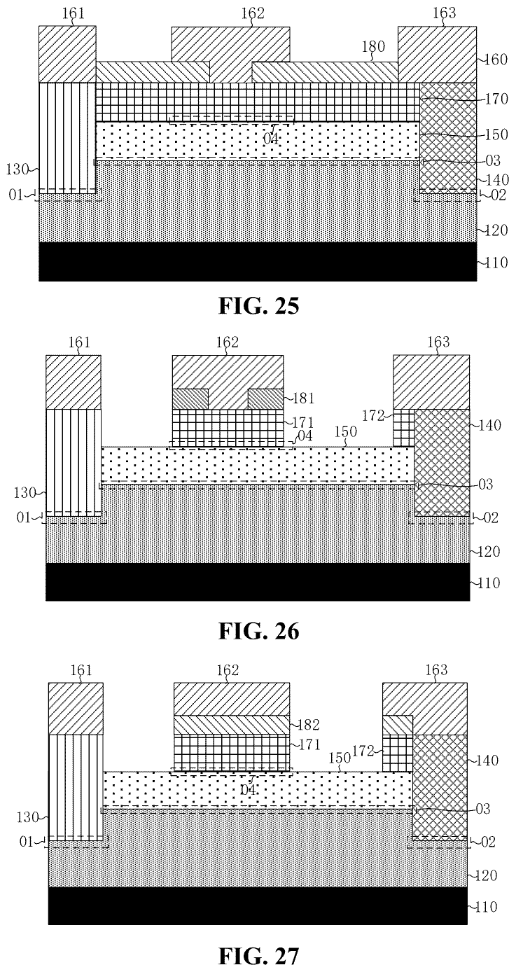

The manufacturing method also includes S320. In S320, as shown in FIG. 24 and FIG. 25, the gate metal layer 162, the source metal layer 161, and the drain metal layer 163 are formed on the side of the barrier layer 150 facing away from the substrate 110. The gate metal layer 162 is located in the gate region 04 and electrically connected to the P-type semiconductor layer 170 through the opening structure. The drain metal layer 163 covers the drain N-type doped layer 140 and part of the P-type semiconductor layer 170 close to the drain N-type doped layer 140.

The metal material layer 160 is deposited on the entire surface and patterned. Part of the metal material layer 160 is removed by etching to form the gate metal layer 162, the source metal layer 161, and the drain metal layer 163.

The manufacturing method also includes S330. In S330, as shown in FIG. 26, with the gate metal layer 162, the source metal layer 161, and the drain metal layer 163 as masks, the passivation layer 180 and the P-type semiconductor layer 170 are etched to form a first blocking layer 181 and a first P-type semiconductor layer 171 between the gate metal layer 162 and the barrier layer 150 and form a second P-type semiconductor layer 172 between the drain metal layer 163 and the barrier layer 150.

Specifically, part of the passivation layer 180 under the gate metal layer 162 forms the first blocking layer 181.

Optionally, P-type impurities in the P-type semiconductor layer 170 are activated by an annealing process before the passivation layer 180 is epitaxially formed. In this case, the P-type impurities in the first P-type semiconductor layer 171 and the P-type impurities in the second P-type semiconductor layer 172 are approximately equal. Alternatively, referring to FIG. 23, P-type impurities in the P-type semiconductor layer 170 are activated by an annealing process after part of the passivation layer 180 corresponding to the gate region 04 and part of the passivation layer 180 adjacent to the drain N-type doped layer 140 are etched to form the opening structure exposing part of the P-type semiconductor layer 170 and before the gate metal layer 162 is formed. In this case, the P-type impurity concentration in part of the first P-type semiconductor layer 171 covered by the first blocking layer 181 is lower than the P-type impurity concentration in part of the first P-type semiconductor layer 171 exposed by the opening structure and lower than the P-type impurity concentration in the second P-type semiconductor layer 172.

FIG. 27 illustrates an intermediate structure of a semiconductor structure according to an embodiment of this disclosure. If the material of the passivation layer 180 includes TiN, after the gate metal layer 162, the source metal layer 161, and the drain metal layer 163 are manufactured, the manufacturing method also includes the following:

In S510, as shown in FIG. 27, with the gate metal layer 162, the source metal layer 161, and the drain metal layer 163 as masks, the passivation layer 180 and the P-type semiconductor layer 170 are etched to form a second blocking layer 182 and a first P-type semiconductor layer 171 between the gate metal layer 162 and the barrier layer 150 and form part of the second blocking layer 182 and a second P-type semiconductor layer 172 between the drain metal layer 163 and the barrier layer 150.

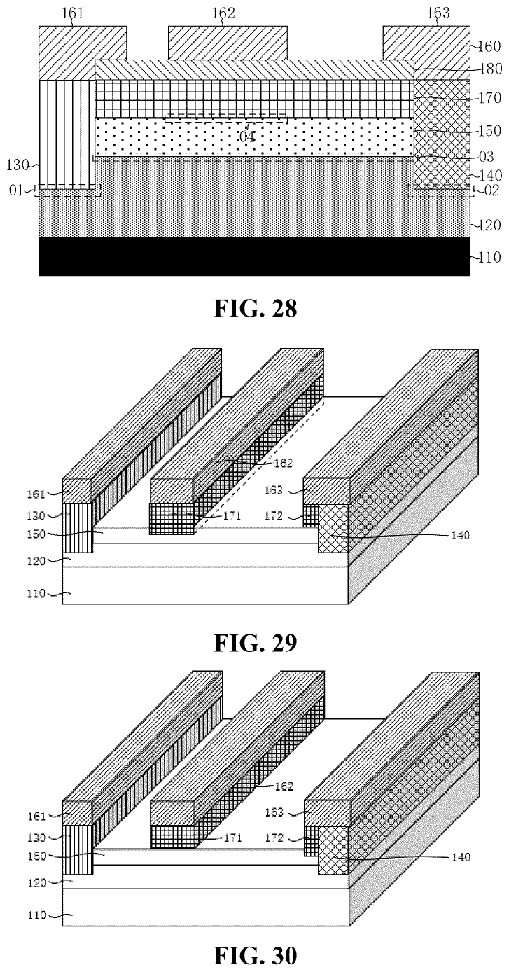

Optionally, FIG. 28 illustrates an intermediate structure of a semiconductor structure according to an embodiment of this disclosure. If the material of the passivation layer 180 includes TiN, after the gate metal layer 162, the source metal layer 161, and the drain metal layer 163 are manufactured, the manufacturing method also includes S610. In S610, as shown in FIG. 28 and FIG. 13, with the gate metal layer 162, the source metal layer 161, and the drain metal layer 163 as masks, the passivation layer 180 and the P-type semiconductor layer 170 are etched to form a second blocking layer 182 and a first P-type semiconductor layer 171 between the gate metal layer 162 and the barrier layer 150, form part of the second blocking layer 182 and a second P-type semiconductor layer 172 between the drain metal layer 163 and the barrier layer 150, and form part of the second blocking layer 182 and a third P-type semiconductor layer 173 between the source metal layer 161 and the barrier layer 150.

Optionally, FIG. 29 is a perspective view of a semiconductor structure according to an embodiment of this disclosure. As shown in FIG. 29, part of the first P-type semiconductor layer 171 is located in the barrier layer 150 so that the thickness of the barrier layer 150 below the first P-type semiconductor layer 171 is less than the thickness of the barrier layer 150 below the second P-type semiconductor layer 172. Moreover, the first P-type semiconductor layer 171 is closer to the channel and closer to the 2DEG, improving the threshold voltage, optimizing the electric field on the sidewall of the gate, and improving the gate breakdown voltage.

Optionally, FIG. 30 is a perspective view of a semiconductor structure according to an embodiment of this disclosure. As shown in FIG. 30, part of the second P-type semiconductor layer 172 is located in the barrier layer 150 so that the thickness of the barrier layer 150 below the first P-type semiconductor layer 171 is greater than the thickness of the barrier layer 150 below the second P-type semiconductor layer 172. Moreover, the second P-type semiconductor layer 172 is closer to the channel and closer to the leakage electrons so that the second P-type semiconductor layer 172 has a stronger ability to deplete the leakage electrons, improving the dynamic performance of the device.

It is to be understood that various forms of the preceding flows may be used with steps reordered, added, or deleted. For example, the steps described in this disclosure may be performed in parallel, in sequence, or in a different order as long as the desired result of the technical solutions provided in this disclosure can be achieved. The execution sequence of these steps is not limited herein.

What is claimed is:

1. A semiconductor structure, comprising:
a substrate;
a channel layer disposed above the substrate, wherein a side of the channel layer facing away from the substrate comprises a source region, a drain region, and an intermediate region between the source region and the drain region;
a source N-type doped layer disposed in the source region, a drain N-type doped layer disposed in the drain region, and a barrier layer disposed in the intermediate region, wherein a side of the barrier layer facing away from the substrate comprises a gate region;
a source metal layer disposed on a side of the source N-type doped layer facing away from the substrate;
a first P-type semiconductor layer and a gate metal layer stacked in sequence in the gate region;
a second P-type semiconductor layer located on a side of the drain N-type doped layer close to the gate region and in contact with the drain N-type doped layer; and
a drain metal layer disposed on a side of the second P-type semiconductor layer facing away from the substrate and a side of the drain N-type doped layer facing away from the substrate.

2. The semiconductor structure of claim 1, wherein a plurality of second P-type semiconductor layers are spaced apart in an extension direction of the drain N-type doped layer.

3. The semiconductor structure of claim 2, wherein the first P-type semiconductor layer comprises a P-type body portion and a plurality of P-type protruding portions spaced apart, and the plurality of P-type protruding portions are located on a side of the P-type body portion close to the drain N-type doped layer; and
the plurality of P-type protruding portions and the plurality of second P-type semiconductor layers are staggered in an extension direction of the gate metal layer.

4. The semiconductor structure of claim 3, wherein a minimum distance from each of the plurality of P-type protruding portions to the drain N-type doped layer is equal to a minimum distance from the P-type body portion to each of the plurality of second P-type semiconductor layers.

5. The semiconductor structure of claim 1, wherein a distance from a surface of the drain N-type doped layer facing away from the substrate to the substrate is less than a distance from a surface of the second P-type semiconductor layer facing away from the substrate to the substrate; or
a surface of the drain N-type doped layer facing away from the substrate is flush with a surface of the second P-type semiconductor layer facing away from the substrate; or
a distance from a surface of the drain N-type doped layer facing away from the substrate to the substrate is greater than a distance from a surface of the second P-type semiconductor layer facing away from the substrate to the substrate.

6. The semiconductor structure of claim 1, wherein a sidewall of the second P-type semiconductor layer is perpendicular to a plane where the substrate is located; or an angle between a sidewall of the second P-type semiconductor layer and a plane where the substrate is located is an acute angle.

7. The semiconductor structure of claim 1, wherein the first P-type semiconductor layer and the second P-type semiconductor layer are both located on the side of the barrier layer facing away from the substrate, and in a direction perpendicular to a plane where the substrate is located, a thickness of the first P-type semiconductor layer is equal to a thickness of the second P-type semiconductor layer.

8. The semiconductor structure of claim 1, further comprising a third P-type semiconductor layer;
wherein the third P-type semiconductor layer is located on a side of the source N-type doped layer close to the gate region and is in contact with the source N-type doped layer; and
the source metal layer is disposed on a side of the third P-type semiconductor layer facing away from the substrate and the side of the source N-type doped layer facing away from the substrate.

9. The semiconductor structure of claim 1, further comprising a first blocking layer;
the first blocking layer is disposed between the gate metal layer and the first P-type semiconductor layer; and
the first blocking layer comprises an opening structure, and the gate metal layer is electrically connected to the first P-type semiconductor layer through the opening structure.

10. The semiconductor structure of claim 9, wherein a P-type impurity concentration in part of the first P-type semiconductor layer covered by the first blocking layer is equal to or lower than a P-type impurity concentration in part of the first P-type semiconductor layer exposed by the opening structure.

11. The semiconductor structure of claim 9, wherein a material of the first blocking layer comprises any one of in-situ SiN, ex-situ SiN, in-situ AlN, ex-situ AlN, aluminum oxide, or SiO₂.

12. The semiconductor structure of claim 9, further comprising an aluminum-containing film layer; and
the aluminum-containing film layer is located in the opening structure, and the gate metal layer is electrically connected to the first P-type semiconductor layer through the aluminum-containing film layer in the opening structure.

13. The semiconductor structure of claim 12, wherein in a direction perpendicular to a plane where the substrate is located, a thickness of the aluminum-containing film layer is less than or equal to a thickness of the first blocking layer.

14. The semiconductor structure of claim 1, further comprising a second blocking layer;
the second blocking layer is disposed between the first P-type semiconductor layer and the gate metal layer; and
a material of the second blocking layer comprises TiN.

15. A manufacturing method of a semiconductor structure, comprising:
sequentially epitaxially forming a channel layer, a barrier layer, and a P-type semiconductor layer above a substrate;
forming a source N-type doped layer in a source region of the channel layer and forming a drain N-type doped layer in a drain region of the channel layer;
forming a gate metal layer, a source metal layer, and a drain metal layer on a side of the barrier layer facing away from the substrate, wherein the gate metal layer is located in the gate region, the source metal layer is located on a side of the source N-type doped layer facing away from the substrate, the drain metal layer is located on a side of the drain N-type doped layer facing away from the substrate, and an orthographically projected area of the drain metal layer on the substrate is greater than an orthographically projected area of the drain N-type doped layer on the substrate; and
with the gate metal layer, the source metal layer, and the drain metal layer as masks, etching the P-type semiconductor layer to form a first P-type semiconductor layer between the gate metal layer and the barrier layer and form a second P-type semiconductor layer between the drain metal layer and the barrier layer.

16. The manufacturing method of the semiconductor structure of claim 15, wherein forming the source N-type doped layer in the source region of the channel layer and forming the drain N-type doped layer in the drain region of the channel layer comprises:
etching through the P-type semiconductor layer, the barrier layer, and part of the channel layer to form a recess in the source region and a recess in the drain region; and
secondarily epitaxially forming a source N-type doped layer in the recess in the source region and secondarily epitaxially forming a drain N-type doped layer in the recess in the drain region.

17. The manufacturing method of the semiconductor structure of claim 15, after sequentially epitaxially forming the channel layer, the barrier layer, and the P-type semiconductor layer above the substrate, the method further comprises:
epitaxially forming a passivation layer on a side of the P-type semiconductor layer facing away from the substrate;
etching through the passivation layer, the P-type semiconductor layer, the barrier layer, and part of the channel layer to form a recess in the source region and a recess in the drain region; and
with the passivation layer as a mask, secondarily epitaxially forming a source N-type doped layer in the recess in the source region and secondarily epitaxially forming a drain N-type doped layer in the recess in the drain region.

18. The manufacturing method of the semiconductor structure of claim 17, wherein a material of the passivation layer comprises any one of in-situ SiN, ex-situ SiN, in-situ AlN, ex-situ AlN, aluminum oxide, or SiO₂; and
after secondarily epitaxially forming the source N-type doped layer and the drain N-type doped layer, the method further comprises:
etching part of the passivation layer corresponding to the gate region and part of the passivation layer adjacent to the drain N-type doped layer to form an opening structure exposing part of the P-type semiconductor layer;
forming the gate metal layer, the source metal layer, and the drain metal layer on the side of the P-type semiconductor layer facing away from the substrate, wherein the gate metal layer is located in the gate region and electrically connected to the P-type semiconductor layer through the opening structure, and the drain metal layer covers the drain N-type doped layer and part of the P-type semiconductor layer close to the drain N-type doped layer; and
with the gate metal layer, the source metal layer, and the drain metal layer as masks, etching the passivation layer and the P-type semiconductor layer to form a first blocking layer and a first P-type semiconductor layer between the gate metal layer and the barrier layer and form a second P-type semiconductor layer between the drain metal layer and the barrier layer.

19. The manufacturing method of the semiconductor structure of claim 18, wherein P-type impurities in the P-type semiconductor layer are activated by an annealing process before the passivation layer is epitaxially formed; or
P-type impurities in the P-type semiconductor layer are activated by an annealing process after part of the passivation layer corresponding to the gate region and part of the passivation layer adjacent to the drain N-type doped layer are etched to form the opening structure exposing part of the P-type semiconductor layer and before the gate metal layer is formed.

20. The manufacturing method of the semiconductor structure of claim 17, wherein a material of the passivation layer comprises TiN; and
after forming the gate metal layer, the source metal layer, and the drain metal layer, the method further comprises:
with the gate metal layer, the source metal layer, and the drain metal layer as masks, etching the passivation layer and the P-type semiconductor layer to form a second blocking layer and a first P-type semiconductor layer between the gate metal layer and the barrier layer and form a second P-type semiconductor layer between the drain metal layer and the barrier layer.
